(19) United States
(12) Patent Application Publication
(10) Pub. No.: US 2019/0294831 A1
(43) Pub. Date: Sep. 26, 2019

(54) MAGNETIC HEAD AND CARD READER

(71) Applicant: NIDEC SANKYO CORPORATION, Suwa-gun (JP)

(72) Inventors: Tetsuo MOCHIDA, Suwa-gun (JP); Hiroshige TAKEDA, Suwa-gun (JP)

(21) Appl. No.: 16/352,061

(22) Filed: Mar. 13, 2019

(30) Foreign Application Priority Data
Mar. 20, 2018 (JP) 2018-052040
Mar. 20, 2018 (JP) 2018-052041

(51) Int. Cl. G06K 7/08; G01R 33/09; G11B 25/04

(52) U.S. Cl. CPC G06K 7/084; G11B 25/04; G01R 33/09

(57) ABSTRACT

A magnetic head structured to detect whether magnetic data are recorded on a medium or not may include a case provided with an opening part formed in a sensor face which faces a side where the medium is passed, a protection member positioned and disposed in the opening part with the sensor face as a reference, and a magneto-resistance effect element disposed in the opening part in a state that at least a part of the magneto-resistance effect element is covered by the protection member.

### CROSS REFERENCE TO RELATED APPLICATION

The present application claims priority under 35 U.S.C. § 119 to Japanese Application No. 2018-052040 filed Mar. 20, 2018, and Japanese Application No. 2018-052041 filed Mar. 20, 2018, the entire contents of both of which are incorporated herein by reference.

### TECHNICAL FIELD

At least an embodiment of the present invention relates to a magnetic head comprising a magneto-resistance effect element and a card reader.

### BACKGROUND

A card reader includes a magnetic head structured to perform processing such as reading and writing of magnetic data to a card which is inserted through a card insertion port. Further, a card reader includes a pre-head which is a magnetic head for detecting whether or not magnetic data are recorded on a card inserted into a card insertion port. A control part of the card reader opens a shutter member provided in the card insertion port and drives a conveyance mechanism structured to convey a card when magnetic data recorded on the card are detected based on a detection signal of the pre-head, and the card is taken into the inside and processing such as reading and writing of magnetic data is performed.

The magnetic head includes a magneto-resistance effect element and a case which accommodates the magneto-resistance effect element. The case includes a sensor face on which a card recorded with magnetic data is slid. This type of magnetic sensor is disclosed in Japanese Patent No. 3775296 (Patent Literature 1). In the magnetic sensor in Patent Literature 1, a wiring member (metal wiring body and external connection terminal) connected with a magneto-resistance effect element and a magnet for generating a bias magnetic field are disposed in an inside of a case, and they are sealed in the inside of the case with resin. Further, a ceramic layer (nickel plating layer containing ceramic particles) for enhancing abrasion resistance of a sensor face on which a card is slid is formed on a surface of the case.

A conventional magnetic sensor is structured so that a yoke is disposed in an inside of a case for forming a magnetic path and the magnetic flux is converged at a position of a magneto-resistance effect element for enhancing detection accuracy by the magneto-resistance effect element. However, when a yoke is used, the number of parts is increased and thus the cost is increased and, in addition, assembling works become complicated.

Further, although the magnetic sensor disclosed in Patent Literature 1 is not provided with a yoke, a bias magnetic field is generated by using a magnet. However, in a magnetic head for generating a bias magnetic field by a magnet, a detection output is also generated for a simple metal card. Therefore, a card where magnetic data are recorded and a simple metal card cannot be distinguished and thus, when the above-mentioned magnetic head is used as a pre-head, a metal card where no magnetic data are recorded may be erroneously detected as a card where magnetic data are recorded.

In order to detect magnetic data recorded on a card by a magneto-resistance effect element without using a yoke and a magnet, the magneto-resistance effect element is required to be disposed in a sensor face and a gap between the card and the magneto-resistance effect element is set to be less than several tens of μm. However, in a case that a magneto-resistance effect element is disposed in a sensor face, abrasion and damage of the magneto-resistance effect element may be occurred by contacting of a card with the sensor face and thus durability is deteriorated. In Patent Literature 1, although a ceramic layer having abrasion resistance is provided on the surface of the case, the magneto-resistance effect element is covered by the case covered by the ceramic layer. Therefore, according to this structure, a gap between the magneto-resistance effect element and a card cannot be set sufficiently small and thus a required detection accuracy cannot be secured.

### SUMMARY

In view of the problems described above, at least an embodiment of the present invention secures detection accuracy of the magnetic head and to restrain deterioration of durability of the magnetic head due to contact with a medium.

In order to attain the above, at least an embodiment of the present invention provides a magnetic head which is structured to detect whether magnetic data are recorded on a medium or not. The magnetic head includes a case formed with an opening part in a sensor face which faces a side where the medium is passed, a protection member which is positioned and disposed in the opening part with the sensor face as a reference, and a magneto-resistance effect element which is disposed in the opening part in a state that at least a part of the magneto-resistance effect element is covered by the protection member.

In at least an embodiment of the present invention, an opening part is formed in a sensor face of a case of the magnetic head, and a magneto-resistance effect element covered by a protection member is disposed in the opening part. According to this structure, although the magneto-resistance effect element is disposed in the opening part of the case so that a gap between a medium and the magneto-resistance effect element is reduced, the magneto-resistance effect element is protected by the protection member. Therefore, damage of the magneto-resistance effect element due to contact of the medium with the sensor face can be restrained and deterioration of the durability is restrained. Further, the protection member is positioned in the opening part with the sensor face as a reference and thus, a distance between the magneto-resistance effect element and the sensor face can be determined by a thickness of the protection member. Therefore, a gap between the magneto-resistance effect element and a medium can be controlled finely, and the gap between the magneto-resistance effect element and the medium can be reduced. Accordingly, the detection accuracy can be secured without using a yoke for guiding magnetic flux to the magneto-resistance effect element. Further, a part cost of a yoke can be eliminated and, in addition, assembling work is also easy.

In at least an embodiment of the present invention, the protection member is made of ceramic. Abrasion resistance of ceramic is high and thus, damage of the magneto-resistance effect element can be restrained and durability of the magnetic sensor can be enhanced. For example, abrasion resistance of hard ceramic such as zirconia is high and thus hard ceramic may be used as a protection member.

In at least an embodiment of the present invention, a first adhesive for fixing the magneto-resistance effect element to the protection member is a hard adhesive, and the first adhesive is spread over a gap space between the protection member and the case, and the first adhesive is spread over a gap space between the magneto-resistance effect element and the case so that the protection member and the magneto-resistance effect element are fixed to the case. According to this structure, each of the protection member and the magneto-resistance effect element can be surely fixed to the case. Further, since a hard adhesive is used as the first adhesive, fixation by the first adhesive can be performed surely and the magneto-resistance effect element can be positioned to the sensor face with a high degree of accuracy. Accordingly, the gap between the magneto-resistance effect element and a medium can be controlled finely and the gap between the magneto-resistance effect element and the medium can be reduced. As a result, detection accuracy can be secured.

In at least an embodiment of the present invention, that an inside of the case is sealed with a second adhesive which is a soft adhesive. When an inside of the case is sealed, a wiring member connected with the magneto-resistance effect element can be protected. Therefore, disconnection and damage of the wiring member can be restrained. Further, in a case that a temperature shock is applied, although stress is applied to the magneto-resistance effect element due to a difference of thermal expansion coefficients of the members, the stress can be relaxed.

In at least an embodiment of the present invention, the case is formed of conductive resin. When the case is made conductive, the case can be grounded and the magneto-resistance effect element can be protected from static electricity. Further, when the case is made of resin instead of metal, a component cost of the case can be reduced.

In at least an embodiment of the present invention, the case is provided with a tube-shaped part and a bottom part which closes one end of the tube-shaped part, and the bottom part structures the sensor face, and an inner face of the tube-shaped part is provided with a fixing part to which a ground line is fixed. According to this structure, the case can be grounded and thus the magneto-resistance effect element can be protected from static electricity.

In at least an embodiment of the present invention, the magnetic head includes a flexible printed circuit board connected with the magneto-resistance effect element, and the ground line is provided in the flexible printed circuit board. According to this structure, a signal line connected with the magneto-resistance effect element and the ground line can be routed together and thus the wiring member can be easily handled at the time of assembling.

Next, at least an embodiment of the present invention provides a card reader including a card insertion part formed with a card insertion port, and a card reader main body having a card conveyance passage connected with the card insertion port and being structured to perform at least one of reading and recording of magnetic data to a card in the card conveyance passage, and the above-mentioned magnetic head is mounted in the card insertion part as a pre-head which is structured to detect whether or not magnetic data are recorded on a card inserted into the card insertion port. According to this card reader, the detection accuracy can be secured without using a yoke in the magnetic head which is mounted as a pre-head and, in addition, deterioration of the durability can be restrained. Further, a component cost of a yoke can be eliminated and assembling work is also easy.

Other features and advantages of the invention will be apparent from the following detailed description, taken in conjunction with the accompanying drawings that illustrate, by way of example, various features of embodiments of the invention.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1A and FIG. 1B are explanatory views showing an internal structure of a card reader including a magnetic head in accordance with at least an embodiment of the present invention and a magnetic card.

FIG. 2A, FIG. 2B and FIG. 2C are a side view, a plan view and a bottom view showing a magnetic head in accordance with at least an embodiment of the present invention.

FIG. 3 is a plan view showing a flexible printed circuit board and a magneto-resistance effect element.

FIG. 4 is a perspective view showing a magnetic head.

FIG. 5 is an exploded perspective view showing a magnetic head.

FIG. 6 is a perspective view showing a magnetic head.

FIG. 7 is an exploded perspective view showing a magnetic head.

FIG. 8A and FIG. 8B are a cross-sectional view showing a magnetic head and an explanatory view showing its assembling method.

FIG. 9A and FIG. 9B are a cross-sectional view showing a magnetic head and an explanatory view showing its assembling method.

### DETAILED DESCRIPTION

A magnetic head 10 and a card reader 1 in accordance with at least an embodiment of the present invention will be described below with reference to the accompanying drawings.

(Card Reader)

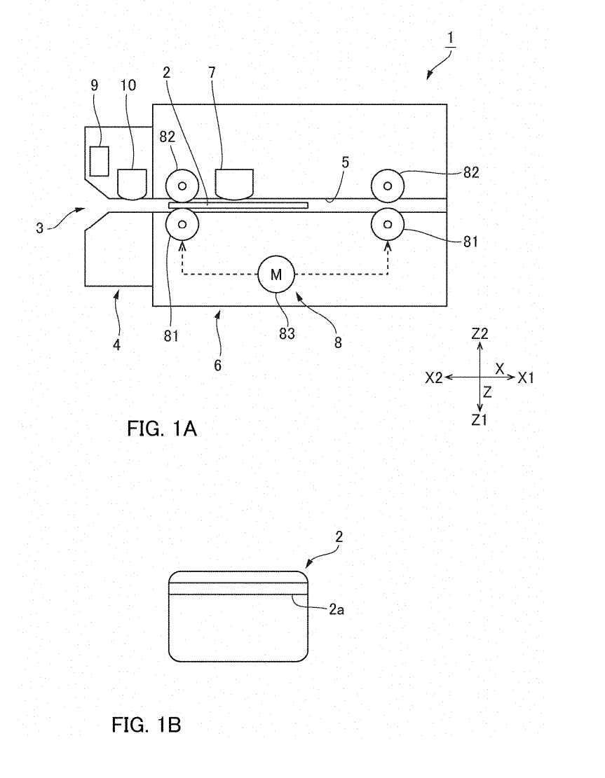

FIG. 1A is an explanatory view schematically showing an internal structure of a card reader 1 including a magnetic head 10 in accordance with at least an embodiment of the present invention, and FIG. 1B is an explanatory view showing a magnetic card. As shown in FIG. 1A, the card reader 1 includes a card insertion part 4 where a card insertion port 3 into which a card 2 is inserted is formed, and a card reader main body 6 in which a card conveyance passage 5 connected with the card insertion port 3 is formed. The card insertion part 4 is fixed to a front end of the card reader main body 6. The card reader main body 6 includes a magnetic head 7 structured to perform at least one of reading and writing of magnetic data to a card 2 passing along the card conveyance passage 5. Further, the card reader main body 6 includes a conveyance mechanism 8 structured to convey a card 2 along the card conveyance passage 5. The conveyance mechanism 8 includes drive rollers 81 and pad rollers 82 structured to sandwich and convey a card 2, and a conveyance motor 83 structured to rotate the drive rollers 81.

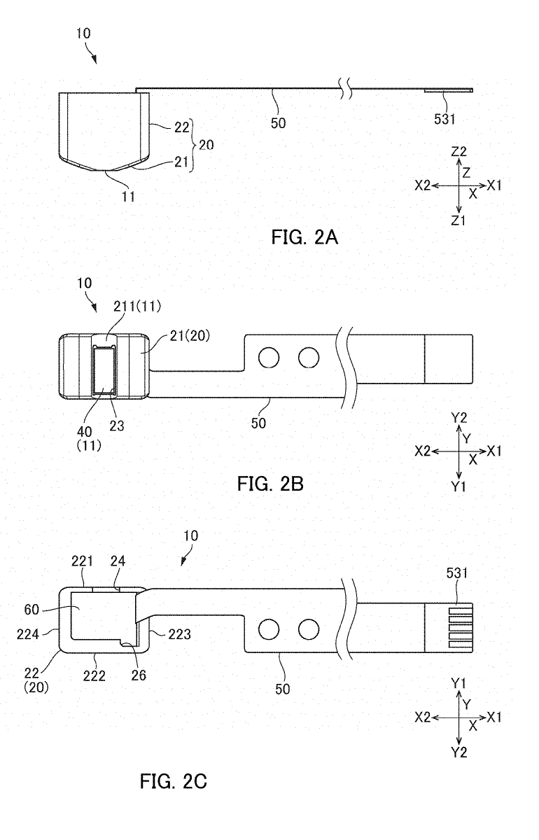

In the present specification, three directions, i.e., “X”, “Y” and “Z” are directions perpendicular to each other. The “X” direction is a front and rear direction of the card reader 1. A card 2 is inserted into the card reader 1 to the “X1” direction and is taken out from the card reader 1 to the “X2” direction. In other words, the “X” direction is a conveyance direction for a card 2. The “Y” direction is a width direction of the card reader 1, and one side in the “Y” direction is referred to as “Y1” and the other side is referred to as “Y2”. The “Z” direction is a height direction of the card reader 1 and is a thickness direction of a card 2 inserted into the card insertion port 3. One side in the “Z” direction is referred to as “Z1” and the other side is referred to as “Z2”. In the description of a magnetic head 10 described below, the three directions of “X”, “Y” and “Z” shown in FIG. 2A through FIG. 9B are shown in a state that the magnetic head 10 is mounted on the card reader 1.

A card 2 is made of vinyl chloride and its thickness is about 0.7-0.8 mm. As shown in FIG. 1B, the card 2 is formed with a magnetic stripe 2a in which magnetic data are recorded. The magnetic stripe 2a is extended in a longitudinal direction of the card 2.

As shown in FIG. 1A, the card insertion part 4 includes an insertion detection sensor 9 structured to detect a card 2 which is inserted into the card insertion port 3. Further, the card insertion part 4 includes a magnetic head 10 which is a pre-head structured to detect that magnetic data are recorded on the card 2. A control part of the card reader 1 detects that the card 2 has been inserted into the card insertion port 3 based on an output of the insertion detection sensor 9. Further, the control part detects that magnetic data are recorded on the card 2 based on an output of the magnetic head 10.

When the control part of the card reader 1 detects that a card 2 is inserted into the card insertion port 3 and, in addition, the control part detects that magnetic data are recorded on the card 2, the control part determines that a card 2 to be processed has been inserted and takes the card 2 into the card conveyance passage 5. In other words, a shutter mechanism not shown provided on a rear side of the card insertion port 3 is operated to open and the conveyance mechanism 8 is driven to convey the card 2 to a position of the magnetic head 7. When the card 2 is passed through the position of the magnetic head 7, a sensor face of the magnetic head 7 slides on a magnetic stripe 2a of the card 2 and processing such as reading and writing of magnetic data is performed.

(Magnetic Head)

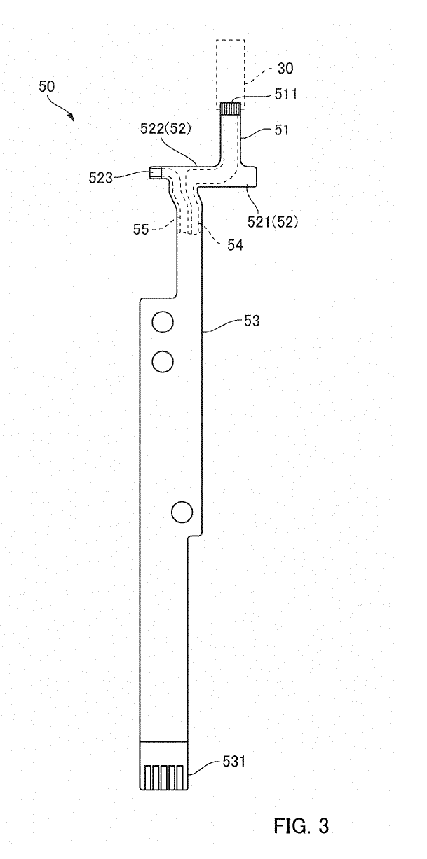

FIG. 2A, FIG. 2B and FIG. 2C are a side view, a plan view and a bottom view showing the magnetic head 10 in accordance with at least an embodiment of the present invention. FIG. 2A is the side view, FIG. 2B is the bottom view, and FIG. 2C is the plan view. The magnetic head 10 includes a case 20, a magneto-resistance effect element 30 (see FIG. 3 and FIG. 5 through FIG. 9B) accommodated in an inside of the case 20, a protection member 40 which protects the magneto-resistance effect element 30, and a flexible printed circuit board 50. A part of the flexible printed circuit board 50 is accommodated in the inside of the case 20 and is connected with the magneto-resistance effect element 30.

As shown in FIG. 2C, one portion of the flexible printed circuit board 50 which is accommodated in the inside of the case 20 is sealed with a soft adhesive 60. The other portion of the flexible printed circuit board 50 is extended to the outside of the case 20 and is connected with a circuit board (not shown) provided in the card reader main body 6. As shown in FIG. 1A, the card reader main body 6 is disposed on the “X1” direction side with respect to the magnetic head 10 which is used as a pre-head mounted in the card insertion part 4. Therefore, the flexible printed circuit board 50 is extended from the case 20 to the “X1” direction. A circuit board with which the flexible printed circuit board 50 is connected is provided with a signal processing circuit which processes a signal of the magneto-resistance effect element 30.

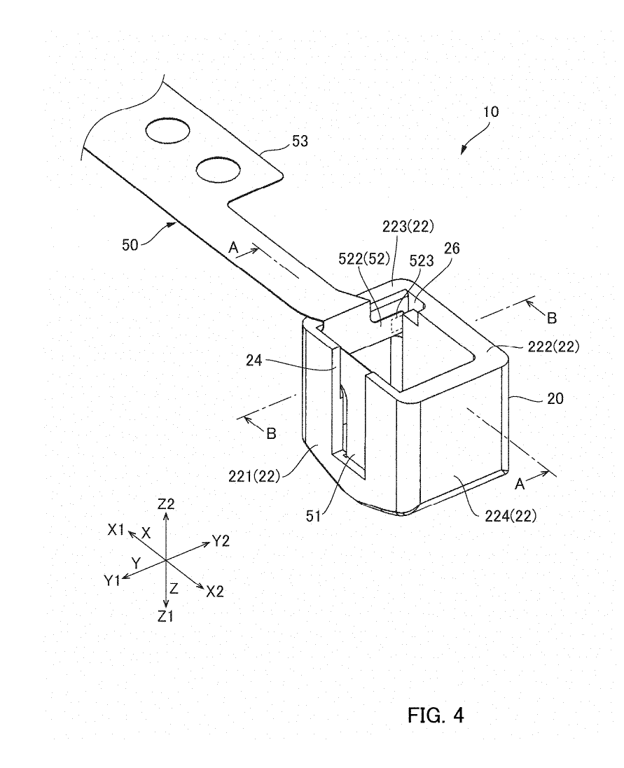

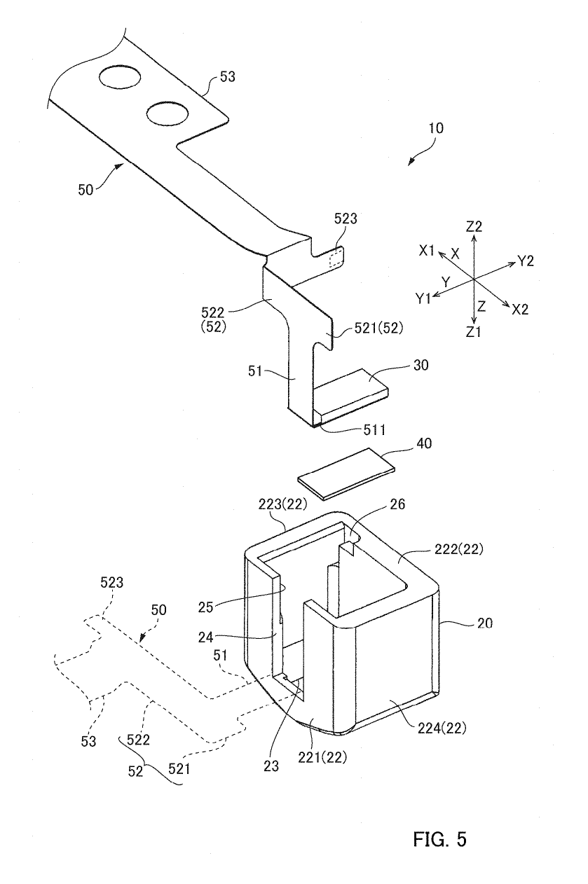

The magnetic head 10 is provided with a sensor face 11 which is a sliding face on which a card 2 is slid. The sensor face 11 faces a side where a card 2 inserted into the card insertion port 3 is passed (to the “Z1” direction in the arrangement in FIG. 1A). As shown in FIG. 2A, the sensor face 11 is provided in a bottom part 21 of the case 20. The case 20 is opened to the “Z2” direction and the inside is formed to be hollow. The case 20 is provided with a tube-shaped part 22 extended in the “Z” direction and a bottom part 21 which closes an end part on the “Z1” direction side of the tube-shaped part 22. As shown in FIG. 2C, the tube-shaped part 22 is provided with a first wall 221 and a second wall 222, which are extended in substantially parallel to the “X” direction, and a third wall 223 and a fourth wall 224 which are extended in substantially parallel to the “Y” direction, and the tube-shaped part 22 is formed in a rectangular tube shape whose dimension in the “X” direction is longer than its dimension in the “Y” direction. A cut-out part 24 (see FIG. 4 and FIG. 5) having a constant width is formed at a center in the “X” direction of the first wall 221 which is located on the “Y1” direction side.

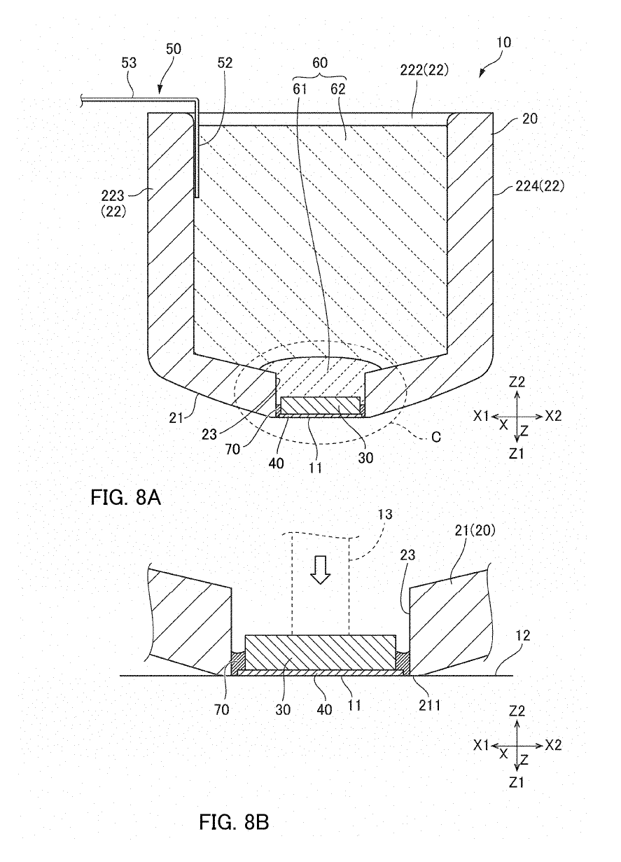

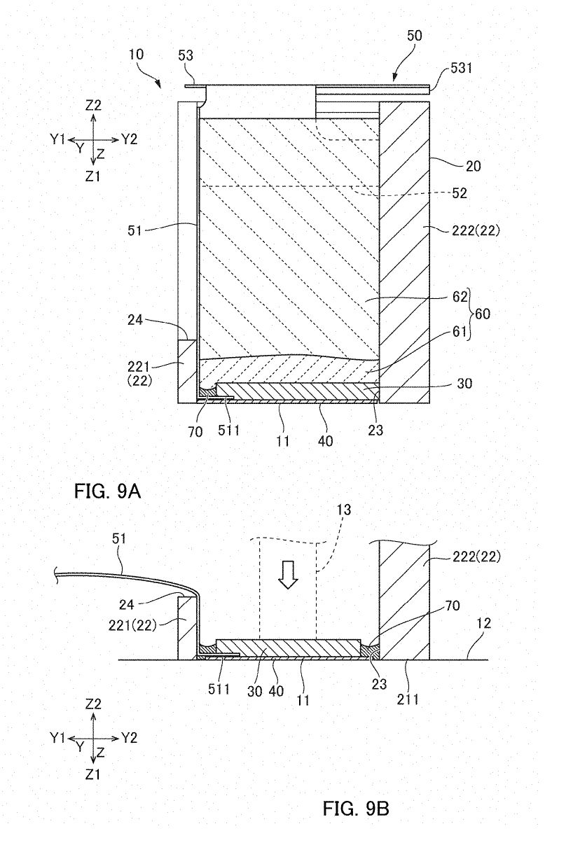

As shown in FIG. 2A, the bottom part 21 is formed in a shape so that its center portion in the “X” direction which is a direction where a card 2 is passed is swollen to the “Z1” direction, and the sensor face 11 is provided at a center in the “X” direction of the bottom part 21. The sensor face 11 is a flat face which is perpendicular to the “Z” direction. As shown in FIG. 2B, the bottom part 21 of the case 20 is formed with a rectangular opening part 23. The sensor face 11 is structured of a flat face part 211 formed in the bottom part 21 so as to surround the opening part 23 and a protection member 40 which is positioned on the same plane as the flat face part 211 and is disposed in the opening part 23. In other words, the protection member 40 is disposed on the same plane as the sensor face 11. The protection member 40 is fixed to the case 20 with a hard adhesive 70 (see FIG. 8A through FIG. 9B).

FIG. 3 is a plan view showing the flexible printed circuit board 50 and the magneto-resistance effect element 30. The flexible printed circuit board 50 has a planar shape as shown in FIG. 3 in a state before the magneto-resistance effect element 30 is fixed and assembled into the case 20. The flexible printed circuit board 50 is provided with a first portion 51 in a straight line shape whose tip end is fixed to the magneto-resistance effect element 30, a second portion 52 connected with an end part of the first portion 51 on an opposite side to a side where the magneto-resistance effect element 30 is fixed, and a third portion 53 which is extended from the second portion 52 to an opposite side to the first portion 51.

A tip end of the first portion 51 is formed with a first terminal part 511 which is connected with the magneto-resistance effect element 30. The magneto-resistance effect element 30 is formed in a rectangular shape, and an end part on one side in its longitudinal direction is fixed to a tip end of the first portion 51 where the first terminal part 511 is provided. The second portion 52 is extended in a straight line shape in a direction perpendicular to the first portion 51 as a whole. The second portion 52 is provided with a protruded part 521 which is protruded to one side in a width direction of the first portion 51 and a protruded part 522 which is protruded to the other side in the width direction of the first portion 51, and a second terminal part 523 is formed at a tip end of the protruded part 522. The third portion 53 is connected with a midway portion of the protruded part 522. The third portion 53 is extended in a direction perpendicular to the second portion 52 as a whole, and a width of an end part on a side connected with the protruded part 522 of the second portion 52 is formed to be thin and a width of a portion on an opposite side to the protruded part 522 is formed to be wide. A third terminal part 531 is formed at an end part of the third portion 53 on an opposite side to the second portion 52.

The flexible printed circuit board 50 includes a flexible substrate and a wiring pattern formed on the flexible substrate. As shown in FIG. 3, the flexible printed circuit board 50 is provided with a wiring pattern structuring a signal line 54 connected with the magneto-resistance effect element 30 and a wiring pattern structuring a ground line 55. The wiring pattern structuring the signal line 54 is extended from the third portion 53 to the first portion 51 through the protruded part 522 of the second portion 52 and is connected with the first terminal part 511 provided at the tip end of the first portion 51. On the other hand, the wiring pattern structuring the ground line 55 is extended from the third portion 53 to the tip end side of the protruded part 522 of the second portion 52 and is connected with the second terminal part 523 provided at the tip end of the protruded part 522. The protruded part 522 in which the ground line 55 is provided structures a branch part which is branched from the first portion 51 provided with the signal line 54 and thus the ground line 55 can be routed to a position different from the bottom part 21 of the case 20 in which the magneto-resistance effect element 30 is disposed. The patterns structuring the signal line 54 and the ground line 55 are extended to the end part of the third portion 53 on an opposite side to the second portion 52 and connected with the third terminal part 531. The ground line 55 is electrically connected with a member having a frame ground potential provided in the card reader main body 6 through the third terminal part 531. Therefore, the second terminal part 523 becomes a frame ground terminal.

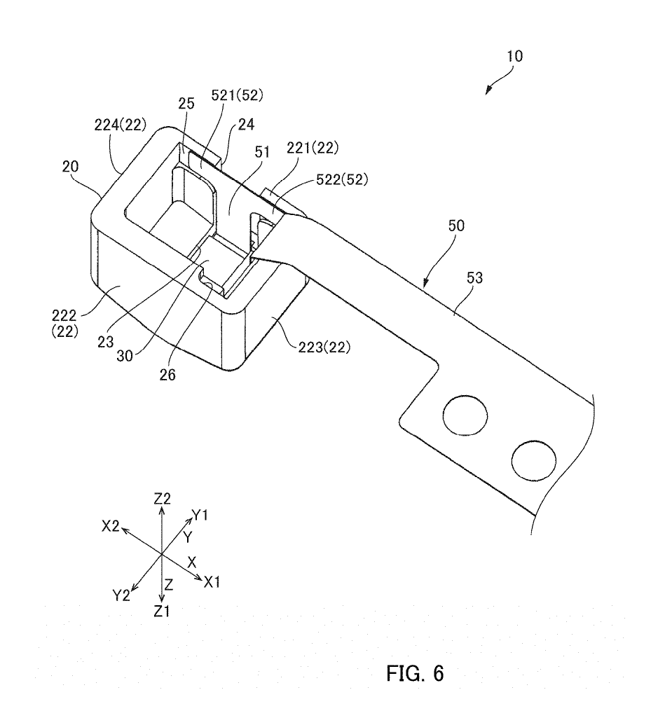

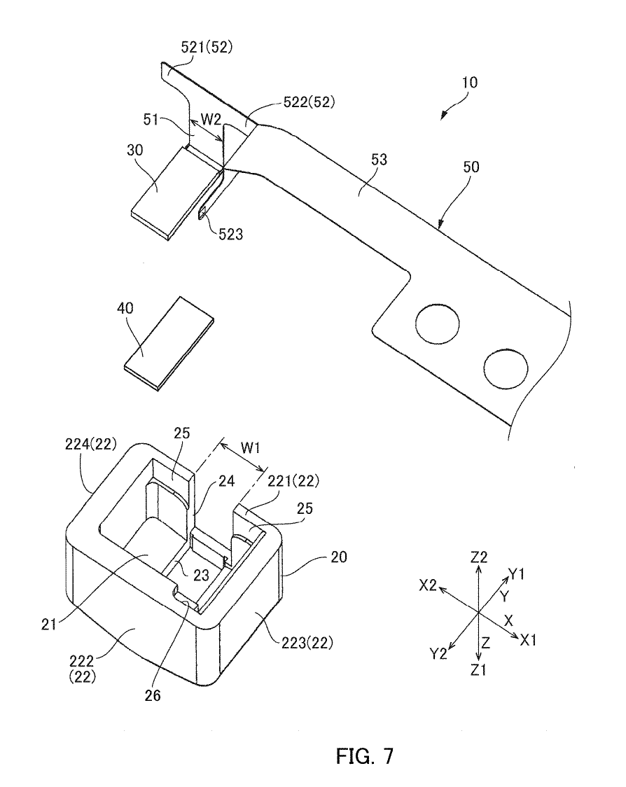

FIG. 4 is a perspective view showing the magnetic head 10 and FIG. 5 is an exploded perspective view showing the magnetic head 10. Further, FIG. 6 is a perspective view showing the magnetic head 10 and FIG. 7 is an exploded perspective view showing the magnetic head 10. FIG. 6 and FIG. 7 are viewed from a different direction from FIG. 4 and FIG. 5. As shown in FIG. 6, the magneto-resistance effect element 30 fixed to the first portion 51 of the flexible printed circuit board 50 is disposed in the opening part 23 of the case 20. As described above, the protection member 40 structuring the sensor face 11 is disposed in the opening part 23, and the magneto-resistance effect element 30 is fixed to an inner side face of the protection member 40. Therefore, the magneto-resistance effect element 30 is positioned at a position having a gap of the same dimension as a thickness of the protection member 40 between the sensor face 11 and the magneto-resistance effect element 30 and, in addition, the magneto-resistance effect element 30 is fixed to the opening part 23 of the case 20 in a protected state that its surface is covered by the protection member 40.

As shown in FIG. 4 and FIG. 6, the flexible printed circuit board 50 is assembled into the inside of the case 20 in a state that the first portion 51 and the second portion 52 are bent. The first portion 51 and the second portion 52 are sealed with the soft adhesive 60 which is injected into the inside of the case 20 and hardened. The soft adhesive 60 is not shown in FIG. 4 and FIG. 6.

The shape of the flexible printed circuit board 50 shown in FIG. 5 shows a bent state by a solid line when it has been assembled into the inside of the case 20, and a broken line shows a midway state that the magnetic head 10 is being assembled. In other words, the shape shown by the broken line indicates a state that the first portion 51 of the flexible printed circuit board 50 is extended to the outside of the case 20 through the cut-out part 24 of the case 20 in a state that the magneto-resistance effect element 30 is disposed in the opening part 23 of the case 20. When the flexible printed circuit board 50 is assembled into the inside of the case 20, the first terminal part 511 with which the magneto-resistance effect element 30 is connected is bent to the “Y2” direction at the tip end of the first portion 51. The magneto-resistance effect element 30 is disposed in the opening part 23 of the case 20 in a state that its longitudinal direction is directed along the “Y” direction. In other words, the magneto-resistance effect element 30 is positioned so that a longitudinal direction of the sensor face 11 is set in the direction (“Y” direction) perpendicular to the “X” direction which is the direction where a card 2 is passed.

When the magneto-resistance effect element 30 is disposed in the opening part 23 of the case 20, the first portion 51 of the flexible printed circuit board 50 is disposed on an inner side of the cut-out part 24 of the case 20. A width “W2” (see FIG. 7) of the first portion 51 is smaller than a width “W1” (see FIG. 7) of the cut-out part 24. Therefore, the first portion 51 can be passed through the cut-out part 24 and the flexible printed circuit board 50 can be extended to the outside of the case 20 as shown by the broken line in FIG. 5. In this embodiment, fixing work of the protection member 40 and the magneto-resistance effect element 30 to the case 20 with a hard adhesive 70 is performed in this state. After that, as shown in FIG. 4 and FIG. 6, the first portion 51 is bent to the “Z2” direction on an inner side of the cut-out part 24 and the second portion 52 is hooked to an inner face of the case 20. As a result, the second portion 52 can be held so as not to project to the outside of the case 20.

As shown in FIG. 6 and FIG. 7, an inner face of the first wall 221 of the case 20 is formed with a holding part 25 which holds the second portion 52. The holding part 25 is a recessed part which is formed in an end part to the “Z2” direction of the inner face of the first wall 221 so as to be recessed to the “Y1” direction, and the holding part 25 is formed on both sides in a width direction of the cut-out part 24. As shown in FIG. 6, a width in the “X” direction of the second portion 52 is set to be larger than the width “W2” of the first portion 51 and the width “W1” of the cut-out part 24. Therefore, the second portion 52 is hooked and held by the case 20 on both sides of the cut-out part 24. In other words, the protruded part 521 of the second portion 52 is hooked and held by the holding part 25 on the “X2” direction side of the cut-out part 24 and a part of the protruded part 522 is hooked and held by the holding part 25 on the “X1” direction side of the cut-out part 24. As shown in FIG. 4, a tip end side of the protruded part 522 is bent to the “Y2” direction and is extended along the inner face of the third wall 223 of the case 20. The third portion 53 is bent to the “X1” direction on the “Z2” direction side of the third wall 223 and is extended to the outside of the case 20 and extended to the “X1” direction.

As shown in FIG. 4 and FIG. 5, a fixing part 26 which is structured by recessing an inner face of the second wall 222 to the “Y2” direction is formed at a corner part where the third wall 223 and the second wall 222 of the case 20 are connected with each other. The second terminal part 523 formed at the tip end of the protruded part 522 is abutted with the inner face on the “X1” direction side of the fixed part 26 and is fixed to the inner face on the “X1” direction side of the fixed part 26 with a conductive adhesive (not shown). In this embodiment, the case 20 is made of conductive resin. As the conductive resin, for example, conductive filler or conductive particles are mixed in resin material and the resin material having electroconductivity is molded for use. The second terminal part 523 which is a frame ground terminal connected with the ground line 55 is fixed to the fixed part 26 with a conductive adhesive and, as a result, the case 20 is grounded.

(Assembling of Magnetic Head)

FIG. 8A is a cross-sectional view showing the magnetic head 10 which is cut at the “A-A” position in FIG. 4. FIG. 8B is an enlarged view showing the region “C” in FIG. 8A and an explanatory view showing an assembling method of the magnetic head 10. FIG. 8B shows a step in which the magneto-resistance effect element 30 and the protection member 40 are fixed in the opening part 23 of the case 20. FIG. 9A is a cross-sectional view showing the magnetic head 10 which is cut at the “B-B” position in FIG. 4. Further, FIG. 9B is an explanatory view showing the assembling method of the magnetic head 10 and, similarly to FIG. 8B, shows a step in which the magneto-resistance effect element 30 and the protection member 40 are fixed in the opening part 23 of the case 20. As shown in FIG. 8A and FIG. 9A, the bottom part 21 of the case 20 is formed with the opening part 23 which is opened in the sensor face 11, and the protection member 40 and the magneto-resistance effect element 30 are disposed in the opening part 23. The protection member 40 and the magneto-resistance effect element 30 are fixed to the case 20 with the hard adhesive 70 which is a first adhesive. Further, the magneto-resistance effect element 30 is covered by the protection member 40 from a side of the sensor face 11.

The protection member 40 is a ceramic plate, for example, a hard ceramic plate such as zirconia. A thickness of the protection member 40 is a dimension which determines a gap between the magneto-resistance effect element 30 and the sensor face 11 and thus the thickness of the protection member 40 is set to the thickness capable of securing detection accuracy of the magneto-resistance effect element 30. In this embodiment, the thickness of the protection member 40 is set within the range between 30 μm and 50 μm. The protection member 40 may be made of material other than zirconia when abrasion resistance is secured. For example, a nonmagnetic metal plate such as alumina or SUS may be utilized.

When the magnetic head 10 is to be assembled, first, in order to fix the protection member 40 and the magneto-resistance effect element 30 in the opening part 23 of the case 20, a first step is performed in which the protection member 40 is positioned in the opening part 23 with the sensor face 11 as a reference. As shown in FIG. 8B and FIG. 9B, in the first step, a case 20 is placed on a reference surface 12 and the sensor face 11 is abutted with the reference surface 12. In this state, a protection member 40 is put into the hollow case 20, and the protection member 40 is fitted to the opening part 23 and is abutted with the reference surface 12.

Next, a second step is performed in which a hard adhesive 70 is applied to a face on the “Z2” direction side (to a face on an opposite side to the sensor face 11) of the protection member 40 disposed in the opening part 23. Successively, in a third step, the magneto-resistance effect element 30 is put into the case 20 and fitted to the opening part 23 and the magneto-resistance effect element 30 is placed on the face of the protection member 40 where the hard adhesive 70 has been applied and, as shown in FIG. 9B, a state is set in which a flexible printed circuit board 50 connected with the magneto-resistance effect element 30 is extended to the outside through the cut-out part 24 of the case 20. Next, in this state, a fourth step is performed. In the fourth step, a pressing pin 13 is put into the case 20 and the magneto-resistance effect element 30 is pressed by a tip end of the pressing pin 13 to the “Z1” direction so that a gap between the magneto-resistance effect element 30 and the sensor face 11 becomes the same as the thickness of the protection member 40. Pressing by the pressing pin 13 is continued until the hard adhesive 70 is heated and hardened.

In this embodiment, the hard adhesive 70 is a low-viscosity adhesive. Therefore, as shown in FIG. 8B, in the fourth step, the hard adhesive 70 is spread over a gap space between the protection member 40 and the opening part 23 of the case 20 and hardened in a state that the gap space is filled with the hard adhesive 70. Accordingly, the magneto-resistance effect element 30 is fixed to the protection member 40 by the hard adhesive 70 and, in addition, the protection member 40 and the case 20 are fixed to each other by the hard adhesive 70, and the magneto-resistance effect element 30 and the case 20 are also fixed to each other by the hard adhesive 70.

Further, the fourth step is performed in a state that the flexible printed circuit board 50 is extended to the outside through the cut-out part 24 of the case 20 and thus the inside of the case 20 can be visually recognized through the cut-out part 24 of the case 20. Therefore, in the fourth step, pressing condition of the magneto-resistance effect element 30 by the pressing pin 13 and the position of the magneto-resistance effect element 30 can be confirmed through the cut-out part 24. Further, in this case, the flexible printed circuit board 50 is prevented from being interfered with the pressing pin 13 in the inside of the case 20.

After the hard adhesive 70 has been hardened, the pressing pin 13 is taken out from the case 20 and a fifth step is performed in which a soft adhesive 60 is injected into the opening part 23 to form a first adhesive layer 61 which covers the magneto-resistance effect element 30. The first adhesive layer 61 fixes the magneto-resistance effect element 30 to the case 20. Successively, a sixth step is performed in which the flexible printed circuit board 50 is returned to the inside of the case 20 and held by the case 20. In the sixth step, as described with reference to FIG. 4 through FIG. 7, the protruded parts 521 and 522 structuring the second portion 52 of the flexible printed circuit board 50 are hooked and held by the holding part 25 of the case 20. Successively, a seventh step is performed in which the second terminal part 523 of the ground line 55 of the flexible printed circuit board 50 is fixed to the fixing part 26 of the case 20 with a conductive adhesive. Next, an eighth step is performed in which a tape or the like is stuck on an outer face of the first wall 221 so as to cover the cut-out part 24 and then, the soft adhesive 60 is further injected up to an upper end of the case 20 to form a second adhesive layer 62 and the inside of the case 20 is sealed.

The soft adhesive 60 is thermosetting resin and thus, in the eighth step, the assembled magnetic head 10 is heated and the soft adhesive 60 is hardened. In this case, although not shown in FIG. 9A, the soft adhesive 60 is spread in the cut-out part 24 of the case 20 over an outer side face of the first portion 51 through a gap space between the first portion 51 of the flexible printed circuit board 50 and the cut-out part 24 so as to cover the outer side face of the first portion 51. Therefore, a layer of the soft adhesive 60 which covers the outer side of the first portion 51 is formed in the cut-out part 24. Further, it may be happened that the hard adhesive 70 spread over the gap space between the inner peripheral face of the opening part 23 and the protection member 40 in the opening part 23 of the sensor face 11 is protruded to the sensor face 11 through the gap space between the protection member 40 and the inner peripheral face of the opening part 23. In this case, a ninth step is performed in which the hard adhesive 70 protruded to the sensor face 11 is removed. As a result, the sensor face 11 is formed to be a flat face and the slidability is enhanced, and a variation with respect to a desired value of a gap dimension between a card 2 sliding on the sensor face 11 and the magneto-resistance effect element 30 is reduced.

### Principal Effects in this Embodiment

As described above, in the magnetic head 10 in this embodiment, the opening part 23 is formed in the sensor face 11 which is provided in the bottom part 21 of the case 20 of the magnetic head 10, and the magneto-resistance effect element 30 covered by the protection member 40 is disposed in the opening part 23. According to this structure, although the magneto-resistance effect element 30 is disposed in the opening part 23 of the case 20 so that a gap between the magneto-resistance effect element 30 and a card 2 which is a medium on which magnetic data are recorded is reduced, the magneto-resistance effect element 30 is protected by the protection member 40. Therefore, damage of the magneto-resistance effect element 30 due to contact of the card 2 with the sensor face 11 can be restrained and deterioration of the durability is restrained. Further, the protection member 40 is positioned in the opening part 23 with the sensor face 11 as a reference and thus, a distance between the magneto-resistance effect element 30 and the sensor face 11 can be determined by a thickness of the protection member 40. Therefore, a gap between the magneto-resistance effect element 30 and a card 2 can be controlled finely, and the gap between the magneto-resistance effect element 30 and the card 2 can be reduced. Accordingly, detection accuracy of the magnetic head 10 can be secured without using a yoke for guiding magnetic flux to the magneto-resistance effect element like a conventional magnetic head and the durability can be secured. Further, a part cost of a yoke can be reduced and, in addition, assembling work of the magnetic head 10 is also easy.

Further, the card reader 1 in this embodiment includes the magnetic head 10 described in this embodiment as a pre-head. Therefore, detection accuracy can be secured without using a yoke in the pre-head and the durability can be secured. Accordingly, a cost of the pre-head can be reduced and the durability can be secured. Further, assembling work is also easy.

In this embodiment, a ceramic plate is used as the protection member 40, and the protection member 40 is formed of zirconia which is hard ceramic. Abrasion resistance of ceramic is high and thus, damage of the magneto-resistance effect element can be restrained and the durability of the magnetic sensor can be enhanced.

In this embodiment, the hard adhesive 70 which is a first adhesive for fixing the magneto-resistance effect element 30 to the protection member 40 is a low-viscosity adhesive. Therefore, the hard adhesive 70 is spread over the gap space between the protection member 40 and the case 20 and the gap space between the magneto-resistance effect element 30 and the case 20 and, in this manner, the protection member 40 and the magneto-resistance effect element 30 are fixed to the case 20. Therefore, each of the protection member 40 and the magneto-resistance effect element 30 can be surely fixed to the case 20. Further, mutual fixation of the protection member 40, the magneto-resistance effect element 30 and the case 20 can be surely performed by using the hard adhesive 70. Therefore, the magneto-resistance effect element 30 can be positioned with respect to the sensor face 11 with a high degree of accuracy. Accordingly, the gap between the magneto-resistance effect element 30 and the card 2 can be controlled finely and the gap between the magneto-resistance effect element 30 and the card 2 can be reduced. As a result, detection accuracy can be secured.

In this embodiment, the inside of the case 20 of the magnetic head 10 is sealed with the soft adhesive 60 which is the second adhesive. As described above, when the inside of the case 20 is sealed, the flexible printed circuit board 50 which is a wiring member connected with the magneto-resistance effect element 30 can be protected. Therefore, disconnection and damage of the flexible printed circuit board 50 can be restrained. Further, since the inside of the case 20 is sealed with the second adhesive which is the soft adhesive 60, even in a case that a temperature shock is applied to the magnetic head 10, stress occurred due to a difference of thermal expansion coefficients of the members and applied to the magneto-resistive element can be relaxed.

In this embodiment, the case 20 of the magnetic head 10 is formed of conductive resin. Further, the case 20 is provided with the tube-shaped part 22 and the bottom part 21 which closes one end of the tube-shaped part 22. The bottom part 21 structures the sensor face 11, and the inner face of the tube-shaped part 22 is provided with the fixing part 26 to which the second terminal part 523 which is a terminal of the ground line 55 is fixed. As described above, the case 20 is made conductive and the ground line 55 is fixed to the case 20 with the conductive adhesive and thus the case 20 can be grounded. Therefore, the magneto-resistance effect element 30 can be protected from static electricity, a failure due to static electricity can be restrained. Further, the case 20 is made of resin instead of metal and thus a component cost of the case 20 can be reduced.

In this embodiment, the ground line 55 is provided in the flexible printed circuit board 50 in which the signal line 54 connected with the magneto-resistance effect element 30 is provided. Therefore, the signal line 54 and the ground line 55 can be routed together and thus the wiring member can be easily handled at the time of assembling. Further, the flexible printed circuit board 50 is formed so that the protruded part 522 of the second portion 52 is branched from the first portion 51 where the signal line 54 is provided, and the ground line 55 is provided in the protruded part 522 which is a branched part from the first portion 51. Therefore, positioning of the second terminal part 523 which is a terminal of the ground line 55 to the fixing part 26 and fixing work of the second terminal part 523 to the fixing part 26 can be performed easily.

Further, in a manufacturing method of the magnetic head 10 in this embodiment, when the magneto-resistance effect element 30 is to be fixed to the protection member 40 disposed in the opening part 23 of the case 20 with the hard adhesive 70 which is the first adhesive, the flexible printed circuit board 50 connected with the magneto-resistance effect element 30 is extended to an outer side of the case 20 through the cut-out part 24 formed in the case 20. According to this structure, the flexible printed circuit board 50 in a flexible shape is prevented from disturbing positional confirmation and pressing work of the magneto-resistance effect element 30. Further, when fixing work of the magneto-resistance effect element 30 to the case 20 is to be performed or the like, disconnection and damage of the wiring member can be restrained. In addition, the position of the magneto-resistance effect element 30 in the inside of the case 20 can be confirmed through the cut-out part 24. Further, after the magneto-resistance effect element 30 has been fixed, the flexible printed circuit board 50 can be returned to the inside of the case 20 through the cut-out part 24 of the case 20 and sealed. Therefore, when the magneto-resistance effect element 30 is to be assembled in the case 20 together with the flexible printed circuit board 50 in a flexible shape, workability can be improved. Further, the magneto-resistance effect element 30 can be positioned with a high degree of accuracy and is fixed.

In this embodiment, the flexible printed circuit board 50 is provided with the first portion 51, which is thinner than a width of the cut-out part 24 of the case 20, and the second portion 52 whose width in the same direction of the width of the first portion 51 is wider than the width of the cut-out part 24. In a state that the flexible printed circuit board 50 is extended to the outside of the case 20 by passing the first portion 51 through the cut-out part 24, the magneto-resistance effect element 30 is pressed and performed with fixing work by hardening the hard adhesive 70. Next, the second portion 52 of the flexible printed circuit board 50 is returned to the inside of the case 20 after the fixing work has been performed, and the second portion 52 is hooked and held by the holding part 25 provided in the case 20. In this embodiment, the second portion 52 is provided with the protruded part 521 protruded to one side in the width direction of the first portion 51 and the protruded part 522 protruded to the other side in the width direction of the first portion 51, and the holding part 25 is a recessed part formed on an inner face of the case 20. Therefore, only when the protruded parts 521 and 522 are disposed in the recessed parts, the flexible printed circuit board 50 can be held by the case 20. According to this structure, the flexible printed circuit board 50 can be held by the case 20 in a stable state and the flexible printed circuit board 50 is prevented from being projected from the case 20. Further, since the second portion 52 is only hooked to the holding part 25 of the case 20, the flexible printed circuit board 50 can be easily held by the case 20.

In this embodiment, after the second portion 52 of the flexible printed circuit board 50 is returned to the case 20 and held by the case 20, the soft adhesive 60 which is the second adhesive is injected into the case 20 and the inside of the case 20 is sealed. When the inside of the case 20 is sealed as described above, the flexible printed circuit board 50 can be protected and thus, disconnection and damage of the flexible printed circuit board 50 can be restrained.

In this embodiment, the hard adhesive 70 is removed which is projected to a side of the sensor face 11 through a gap space between the opening part 23 of the case 20 and the protection member 40. Therefore, a gap between a card 2 which slides on the sensor face 11 and the magneto-resistance effect element 30 can be determined by a thickness of the protection member 40. Accordingly, a gap between a card 2 and the magneto-resistance effect element 30 can be controlled finely and the gap between the magneto-resistance effect element 30 and the card 2 can be reduced. As a result, detection accuracy can be secured without using a yoke.

### Modified Embodiments

In the embodiment described above, the signal line 54 and the ground line 55 are provided in the flexible printed circuit board 50. However, the signal line 54 and the ground line 55 may be structured of another wiring member such as a lead wire.

In the embodiment described above, in order to fix the magneto-resistance effect element 30 to the case 20, the soft adhesive 60 is injected in the opening part 23 from an upper side of the magneto-resistance effect element 30 to form the first adhesive layer 61 and, in addition, in order to seal the flexible printed circuit board 50 in the case 20, the soft adhesive 60 is injected into the case 20 to form the second adhesive layer 62. However, the first adhesive layer 61 and the second adhesive layer 62 may be made of different types of adhesive or made of the same adhesive.

In the embodiment described above, the holding part 25 by which the second portion 52 of the flexible printed circuit board 50 is held in the case 20 is a recessed part formed on an inner face of the case 20. However, a hook-shaped protruded part may be provided on an inner face of the case 20 for holding the second portion 52 between the inner face of the case 20 and the hook-shaped protruded part instead of providing a simple recessed part. Alternatively, it may be structured that a wall thickness of the case 20 is increased so that a groove into which the second portion 52 can be inserted.

In the embodiment described above, a medium on which magnetic data are recorded is a card 2. However, a medium where magnetic data are recorded may be a medium other than a card.

### Second Embodiment

In a case that a wiring member in a flexible shape is assembled in an inside of a case of a magnetic head together with a magneto-resistance effect element, the wiring member is not stable at the time of assembling and workability is deteriorated and thus the wiring member may be damaged. Further, when the magneto-resistance effect element is to be fixed, the magneto-resistance effect element is concealed by the wiring member and is not visually observed and thus, positional confirmation of the magneto-resistance effect element and pressing work of the magneto-resistance effect element are hard to be performed. Especially, in a case that the magneto-resistance effect element is positioned and assembled so that a gap between a card sliding on the sensor face and the magneto-resistance effect element is set to be several tens of μm, the magneto-resistance effect element is required to be positioned with respect to the sensor face of the case with a high degree of accuracy and assembled. However, when a wiring member in a flexible shape is used, it is difficult that the magneto-resistance effect element is positioned and assembled with a high degree of accuracy.

In view of the problem described above, an objective of at least an embodiment of the present invention is to improve workability when a wiring member in a flexible shape is assembled in an inside of a case of a magnetic head together with a magneto-resistance effect element.

In order to attain the above objective, at least an embodiment of the present invention provides a manufacturing method of a magnetic head structured to detect whether magnetic data are recorded on a medium or not. The manufacturing method includes positioning a protection member in an opening part of a case in which the opening part is formed in a sensor face facing a side where a medium is to be passed with the sensor face as a reference, applying a first adhesive to a face of the protection member on an opposite side to the sensor face, disposing a magneto-resistance effect element on the face where the first adhesive has been applied, extending a wiring member connected with the magneto-resistance effect element to an outer side of the case through a cut-out part formed in the case, hardening the first adhesive while pressing the magneto-resistance effect element from an opposite side to the sensor face, and injecting a second adhesive in an inside of the case so as to cover the magneto-resistance effect element and hardening the second adhesive.

In at least an embodiment of the present invention, when the magneto-resistance effect element disposed in the opening part of the case is to be fixed to the protection member by the first adhesive, the wiring member connected with the magneto-resistance effect element is extended to an outer side of the case through the cut-out part formed in the case. According to this structure, the wiring member in a flexible shape can be prevented from disturbing positional confirmation and pressing work of the magneto-resistance effect element. Further, when fixing work of the magneto-resistance effect element to the case is performed, disconnection, damage and the like of the wiring member can be restrained. In addition, the position of the magneto-resistance effect element in the inside of the case can be confirmed through the cut-out part. Further, after the magneto-resistance effect element has been fixed, the wiring member can be returned to the inside of the case through the cut-out part of the case and sealed. Therefore, workability can be improved when the magneto-resistance effect element is to be assembled in the inside of the case together with the wiring member in a flexible shape. Further, the magneto-resistance effect element can be positioned and fixed with a high degree of accuracy.

In at least an embodiment of the present invention, the wiring member is structured of a flexible printed circuit board. When a flexible printed circuit board is used as the wiring member, positioning and fixing work can be easily performed while using the wiring member in a flexible shape.

In at least an embodiment of the present invention, the flexible printed circuit board is provided with a first portion, which is thinner than a width of the cut-out part, and a second portion connected with the first portion and, in a state that the flexible printed circuit board is extended to an outer side of the case by passing the first portion through the cut-out part, a first adhesive is hardened and, after the first adhesive has been hardened, the first portion and the second portion are returned to the inside of the case, and the second portion is hooked to a holding part provided in the case and held. According to this structure, the flexible printed circuit board can be held by the case in a stable state and the flexible printed circuit board is prevented from projecting from the case. Further, the flexible printed circuit board can be easily held by the case by only hooking the second portion whose width is wider than the cut-out part to the holding part of the case.

For example, the second portion is provided with protruded parts which are protruded to both sides in a width direction of the first portion, and the holding part is a recessed part which is formed on an inner face of the case. According to this structure, the flexible printed circuit board can be held in the case only by disposing the protruded parts in the recessed part of the inner face of the case.

In at least an embodiment of the present invention, the case is formed of conductive resin, the flexible printed circuit board is provided with a branched part which is branched from the first portion, the branched part is provided with a ground line, the branched part is routed to a fixing part provided in the case, and the branched part is fixed to the fixing part with a conductive adhesive. According to this structure, the case can be grounded and thus the magneto-resistance effect element can be protected from static electricity. Further, since the ground line is provided in the branched part of the flexible printed circuit board, positioning and fixing work of the ground line can be performed easily.

In at least an embodiment of the present invention, the second portion is returned to the case and, after the second portion is held by the case, a second adhesive is injected into the inside of the case and the inside of the case is sealed. When the inside of the case is sealed, the flexible printed circuit board is protected and thus, disconnection and damage of the flexible printed circuit board can be restrained.

In at least an embodiment of the present invention, the first adhesive projected to a side of the sensor face through a gap space between the opening part and the protection member is removed. According to this structure, a gap between a medium sliding on the sensor face and the magneto-resistance effect element can be controlled by a thickness of the protection member. Therefore, a gap between the magneto-resistance effect element and a medium can be controlled finely and the gap between the magneto-resistance effect element and the medium can be reduced. Accordingly, detection accuracy can be secured without using a yoke for guiding magnetic flux to the magneto-resistance effect element.

Next, at least an embodiment of the present invention is a magnetic head for detecting whether magnetic data are recorded on a medium or not, and the magnetic head is manufactured in the above-mentioned manufacturing method of the magnetic head. In the card reader in which the above-mentioned magnetic head is used, workability at the time of assembling of the magnetic head which is mounted as a pre-head is satisfactory. Further, the magneto-resistance effect element can positioned and fixed with a high degree of accuracy in the inside of the case of the magnetic head.

### Principal Effects in Second Embodiment

In at least an embodiment of the present invention, when the magneto-resistance effect element is to be fixed to the protection member disposed in the opening part of the case with the first adhesive, the wiring member connected with the magneto-resistance effect element is extended to an outer side of the case through the cut-out part formed in the case. According to this structure, the wiring member in a flexible shape can be prevented from disturbing positional confirmation and pressing work of the magneto-resistance effect element. Further, when work is to be performed in which the magneto-resistance effect element is fixed to the case, disconnection or damage of the wiring member can be restrained. In addition, positional confirmation of the magneto-resistance effect element in an inside of the case can be performed through the cut-out part. Further, the wiring member can be returned to the inside of the case through the cut-out part of the case and sealed after the magneto-resistance effect element is fixed. Therefore, workability can be improved when the magneto-resistance effect element is to be assembled in the case together with the wiring member in a flexible shape. Further, the magneto-resistance effect element can be positioned and fixed with a high degree of accuracy.

While the description above refers to particular embodiments of the present invention, it will be understood that many modifications may be made without departing from the spirit thereof. The accompanying claims are intended to cover such modifications as would fall within the true scope and spirit of the present invention.

The presently disclosed embodiments are therefore to be considered in all respects as illustrative and not restrictive, the scope of the invention being indicated by the appended claims, rather than the foregoing description, and all changes which come within the meaning and range of equivalency of the claims are therefore intended to be embraced therein.

What is claimed is:

1. A magnetic head which is structured to detect whether magnetic data are recorded on a medium or not, the magnetic head comprising:
a case comprising an opening part formed in a sensor face which faces a side where the medium is passed;
a protection member which is positioned and disposed in the opening part with the sensor face as a reference; and
a magneto-resistance effect element which is disposed in the opening part in a state that at least a part of the magneto-resistance effect element is covered by the protection member.

2. The magnetic head according to claim 1, wherein the protection member comprises ceramic.

3. The magnetic head according to claim 1, further comprising a first adhesive structured to fix the magneto-resistance effect element to the protection member,
wherein the first adhesive is a hard adhesive, and
wherein the first adhesive is spread over a gap space between the protection member and the case, and the first adhesive is spread over a gap space between the magneto-resistance effect element and the case so that the protection member and the magneto-resistance effect element are fixed to the case.

4. The magnetic head according to claim 1, wherein an inside of the case is sealed with a second adhesive which is a soft adhesive.

5. The magnetic head according to claim 1, wherein the case comprises a conductive resin.

6. The magnetic head according to claim 5, wherein
the case comprises a tube-shaped part and a bottom part which closes one end of the tube-shaped part,
the bottom part structures the sensor face, and
an inner face of the tube-shaped part comprises a fixing part to which a ground line is fixed.

7. The magnetic head according to claim 6, further comprising a flexible printed circuit board connected with the magneto-resistance effect element,
wherein the ground line is provided in the flexible printed circuit board.

8. The magnetic head according to claim 2, further comprising a first adhesive structured to fix the magneto-resistance effect element to the protection member,
wherein the first adhesive is a hard adhesive, and
wherein the first adhesive is spread over a gap space between the protection member and the case, and the first adhesive is spread over a gap space between the magneto-resistance effect element and the case so that the protection member and the magneto-resistance effect element are fixed to the case.

9. The magnetic head according to claim 8, wherein an inside of the case is sealed with a second adhesive which is a soft adhesive.

10. The magnetic head according to claim 9, wherein the case comprises a conductive resin.

11. The magnetic head according to claim 10, wherein
the case comprises a tube-shaped part and a bottom part which closes one end of the tube-shaped part,
the bottom part structures the sensor face, and
an inner face of the tube-shaped part comprises a fixing part to which a ground line is fixed.

12. The magnetic head according to claim 11, further comprising a flexible printed circuit board connected with the magneto-resistance effect element,
wherein the ground line is provided in the flexible printed circuit board.

13. The magnetic head according to claim 3, wherein an inside of the case is sealed with a second adhesive which is a soft adhesive.

14. The magnetic head according to claim 13, wherein the case comprises a conductive resin.

15. The magnetic head according to claim 3, wherein the case comprises a conductive resin.

16. The magnetic head according to claim 4, wherein the case comprises a conductive resin.

17. The magnetic head according to claim 16, wherein
the case comprises a tube-shaped part and a bottom part which closes one end of the tube-shaped part,
the bottom part structures the sensor face, and
an inner face of the tube-shaped part comprises a fixing part to which a ground line is fixed.

18. The magnetic head according to claim 17, further comprising a flexible printed circuit board connected with the magneto-resistance effect element,
wherein the ground line is provided in the flexible printed circuit board.

19. A card reader for use with a card, the card reader comprising:
a card insertion part comprising a card insertion port;
a card reader main body comprising a card conveyance passage connected with the card insertion port, the card reader main body being structured to perform at least one of reading and recording of magnetic data to the card in the card conveyance passage; and
a magnetic head which is structured to detect whether magnetic data are recorded the card, the magnetic head comprising:
a case comprising an opening part formed in a sensor face which faces a side where the card is passed;
a protection member which is positioned and disposed in the opening part with the sensor face as a reference; and
a magneto-resistance effect element which is disposed in the opening part in a state that at least a part of the magneto-resistance effect element is covered by the protection member
wherein the magnetic head is mounted in the card insertion part as a pre-head.

20. The card reader according to claim 19,
wherein the protection member comprises ceramic;
wherein the magnetic head further comprises a first adhesive structured to fix the magneto-resistance effect element to the protection member,
wherein the first adhesive is a hard adhesive, and
wherein the first adhesive is spread over a gap space between the protection member and the case, and the first adhesive is spread over a gap space between the magneto-resistance effect element and the case so that the protection member and the magneto-resistance effect element are fixed to the case;
wherein an inside of the case is sealed with a second adhesive which is a soft adhesive;
wherein the case comprises a conductive resin.
wherein the case comprises a tube-shaped part and a bottom part which closes one end of the tube-shaped part;
wherein the bottom part structures the sensor face;
wherein an inner face of the tube-shaped part comprises a fixing part to which a ground line is fixed;
wherein the magnetic head further comprises a flexible printed circuit board connected with the magneto-resistance effect element,
wherein the ground line is provided in the flexible printed circuit board.
